(19) United States
(12) Patent Application Publication
(10) Pub. No.: US 2010/0122727 A1
(43) Pub. Date: May 20, 2010

(54) Method for fabricating III-V compound semiconductor solar cell and structure thereof

(76) Inventors: Yi-An Chang, Hsinchu Hsien (TW); Chun-Lung Yu, Hsinchu Hsien (TW); I-Tsung Wu, Hsinchu Hsien (TW); Rong-Hwei Yeh, Hsinchu Hsien (TW); Ruei-Chin Wang, Hsinchu Hsien (TW); Li-Hung Lai, Taichung (TW); Li-Wen Lai, Hsinchu Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/292,230

(22) Filed: Nov. 14, 2008

(51) Int. Cl. H01L 31/042; H01L 31/18

(52) U.S. Cl. 136/256; 438/72; 257/E31.127

(57) ABSTRACT

A method for fabricating a III-V compound semiconductor solar cell includes forming a window layer made of III-V compound material over a top surface of an solar cell structure; forming a periodic array of hole textures of the window layer by using a lithography and etching process; and depositing an anti-reflection coating film to cover the window layer. A III-V compound solar cell structure is also provided to enhance the conversion efficiency of photovoltaic.

### BACKGROUND OF THE INVENTION

1. Field of the Invention

The present invention relates to a solar cell, and more particularly, to a III-V compound semiconductor solar cell and its fabrication method.

2. Background of the Related Art

The intensity of the incident light onto an absorption layer, indicative of the absorption efficiency, is an important factor affecting the conversion efficiency of the solar cell. In general, the higher absorption efficiency, is, the higher conversion efficiency is.

A surface texture process is commonly applied on the surface of the solar cell to increase the absorption efficiency (reducing reflection). For example, a silicon solar cell is soaked into KOH solution of an anisotropic etching process to form pyramid like textures on the surface of the silicon solar cell. Since the III-V compound semiconductor materials, such as GaAs, InP, or InGaP, are being developed to application of the solar cell due to its higher conversion efficiency of photovoltaic feature. To increase the benefit of the application and to enhance the conversion efficiency of the III-V compound solar cell, forming a texture surface on the III-V compound semiconductor solar cell can be applied.

### SUMMARY OF THE INVENTION

The present invention is directed to provide a method for fabricating a III-V compound semiconductor solar cell and a structure thereof. The method comprises applying the lithography and etching process to form a periodic array of hole textures on the surface of III-V compound semiconductor solar cell. The texture on the surface of the solar cell increases the transmission of the incident light and the absorption of the incident light. The sunlight passes through the holes, reaches the absorption layer and is absorbed thereby to increase the generated short-circuit current and open-circuit voltage. Therefore, the conversion efficiency of photovoltaic of the solar cell can be enhanced.

An example method for fabricating a III-V compound semiconductor solar cell is described to illustrate an embodiment of this the present invention as follows, which includes providing a solar cell structure comprising a window layer made of III-V compound material formed on the top surface of the solar cell structure, a periodic array of hole textures is formed of the window layer by using the lithography and etching process to form a patterned window layer. Next, an anti-reflection coating film is formed to cover the patterned window layer.

An example structure of a III-V compound semiconductor solar cell is described to illustrate an embodiment of the present invention as follows. The solar cell structure comprises the patterned window layer made of III-V compound material formed over the top surface of the solar cell structure. The patterned window layer comprises a periodic array of holes and an anti-reflection coating film covering the patterned window layer.

### BRIEF DESCRIPTION OF THE DRAWINGS

FIG. 1a to FIG. 1c illustrates the flow diagrams that illustrate a method for fabricating III-V compound semiconductor solar cell in accordance with an embodiment of the present invention;

FIG. 2 shows the SEM picture from the top view of a III-V compound semiconductor solar cell structure in accordance with an embodiment of the present invention;

FIG. 3 shows the reflectance of the different process treatments on the top surface of the solar cells as a function of the wavelength.

### DETAILED DESCRIPTION OF THE INVENTION

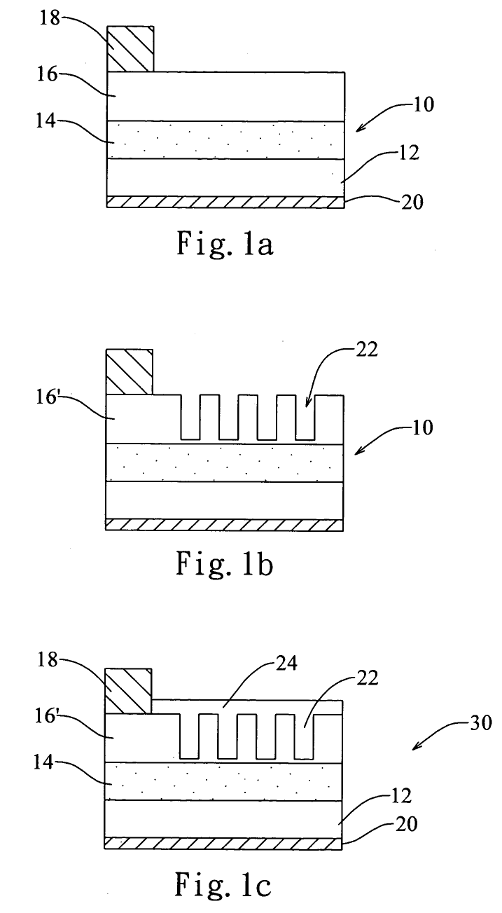

FIG. 1a to FIG. 1c are the flow diagrams that illustrate a method for fabricating a III-V compound semiconductor solar cell in accordance with an embodiment of the present invention. It should be mentioned that the structure of the solar cell illustrated in the drawings are not illustrated in its actual dimensions. First, referring to FIG. 1a, a solar cell structure 10 is provided, which comprises a substrate 12, an absorption layer 14 formed on the substrate 12, a window layer 16 formed on the absorption layer 14, an upper metal electrode 18 formed on the window layer 16 and a rear contact 20 formed below the substrate 12. The window layer 16 is made of III-V compound material, such as an InAlP layer. Next, referring to FIG. 1b, a period of holes 22 is formed of the window layer 16 to form a patterned window layer 16′. In an embodiment of the present invention, the holes may be arranged in an array and the process of forming the holes in the window layer 16 includes, for example but not limited to, a photolithography process, which includes using a mask (not shown) and performing an exposure process to transfer a pattern over the top surface of the solar cell structure 10, a surface of window layer 16 accordingly, and then performing an etching process to form the holes 22 of the window layer 16 to form the patterned window layer 16′. Next, referring to FIG. 1c, an anti-reflection coating film 24 is formed over the patterned window layer 16′ covering the holes 22 by using a suitable method, for example, sputtering or evaporation method.

FIG. 1c is a schematic plot that shows a III-V compound semiconductor solar cell structure. As shown in FIG. 1c, the III-V compound semiconductor solar cell 10 comprises the substrate 12, the absorption layer 14, the patterned window layer 16′, a front contact 18, a rear contact 20 and the anti-reflection coating film 24. The absorption layer 14 is formed on the substrate 12, and the absorption layer 14 comprises a single-junction structure or a multi-junction structure. The patterned window layer 16′ is formed on the absorption layer 14, wherein the patterned window layer 16′ comprises a pattern of a periodic array of holes 22 formed therein. The anti-reflection coating film 24 covers the patterned window layer 16′. The front contact 18 is formed over portion of the patterned window layer 16′, and the rear contact 20 is formed below the substrate 12.

In the present embodiment, a thickness of the window layer 16 is between 200 nm and 300 nm. Various masks may be applied in the lithography process according to the size of the holes 22 and the density of the periodic array of holes for satisfying the requirement of the solar cell. In the present embodiment, the size of hole is between 5 μm and 20 μm.

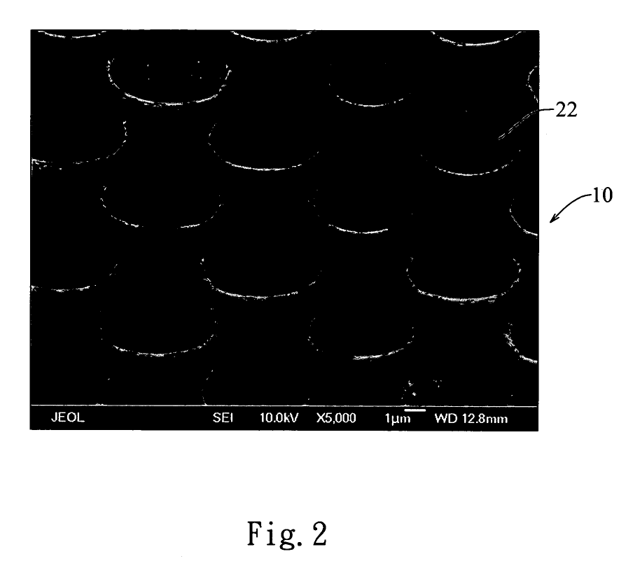

FIG. 2 shows the SEM picture from the top view of a III-V compound semiconductor solar cell structure. As illustrated in FIG. 2, the distribution of the holes is periodic and forms a texture on top of the III-V compound semiconductor solar cell surface 10.

In the present embodiment, the patterned window layer 16′ not only increases the surface area of the light incident surface of the III-V compound semiconductor solar cell 10 but also serve to trap the incident light. When the light is incident on the anti-reflection coating film 24, some of the incident light transmits through the holes 22 and are absorbed by the absorption layer 14, while some of the incident light may strike on the sidewalls of the holes 22 at different incident angles and are repeatedly reflected between the sidewalls of the holes 22 and are directed toward the absorption layer 14, which are ultimately absorbed by the absorption layer 14. Thus, the patterned window layer, which forms the texture surface, serves to trap the incident light and enhance transmission of the incident light. Owing to the different sizes of the hole, the conversion efficiency of the solar cell varies correspondingly. Table 1 lists the parameters and conversion efficiency of different solar cell structures, for example, a traditional solar cell structure without the patterned window layer with array of holes (hereinafter, referred to as traditional structure), a solar cell structure with the patterned window layer including 10 μm holes (hereinafter, referred to as 10 μm structure), and the solar cell structure with the patterned window layer including 5 μm holes (hereinafter, referred to as 5 μm structure). As can be inferred from Table 1, the efficiencies of the traditional structure, 10 μm structure and 5 μm structure are 13.86%, 15.18% and 15.93% under AM 1.5 g (100 mW/cm²) illumination at 25° C., respectively.

TABLE 1
the parameters and conversion efficiency of different solar cell
structures

| AM 1.5 g | traditional structure | 10 μm structure | 5 μm structure |
|---|---|---|---|
| J_{sc} (mA/cm²) | 13.36 | 14.19 | 14.8 |
| V_{oc} (V) | 1.33 | 1.41 | 1.41 |
| FF | 0.78 | 0.759 | 0.763 |
| Jₘ (mA/cm²) | 12.62 | 13.02 | 13.13 |
| Vₘ (V) | 1.1 | 1.17 | 1.16 |
| Pₘ (mW) | 13.86 | 15.18 | 15.93 |
| Efficiency (%) | 13.86 | 15.18 | 15.93 |

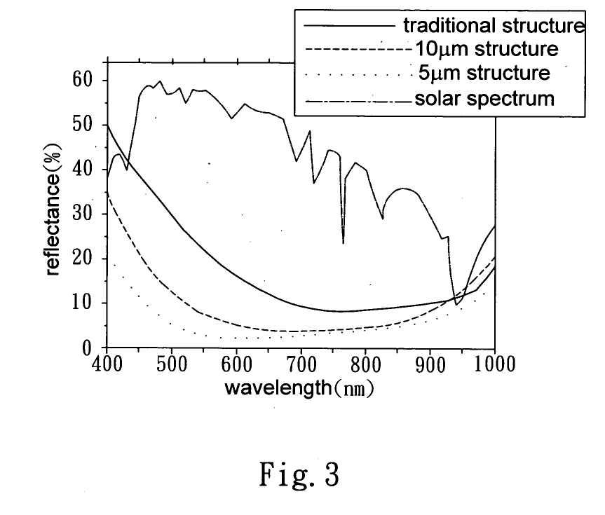

FIG. 3 shows the reflectance of the different process treatments on the top surface of the solar cells as a function of the wavelength. Also, the solar spectrum is illustrated by the curve illustrated in FIG. 3. As can be seen from FIG. 3, the 10 μm structure and the 5 μm structure both have relatively lower reflectance when compared to the traditional structure.

In a summary, the present invention proposes forming a texture surface of the solar cell to increase the surface area of the light absorption region and the incident light transmission to enhance the light absorption of a III-% V compound solar cell. Thus, the generated short-circuit current and open-circuit voltage are increased and therefore the conversion efficiency of the III-V compound solar cell are enhanced, respectively.

Although the present invention has been explained in relation to its preferred embodiment, it is to be understood that other modifications and variation can be made without departing the spirit and scope of the invention as hereafter claimed.

What is claimed is:

1. A method for fabricating a III-V compound semiconductor solar cell, comprising:
providing a solar cell structure comprising a window layer comprised of III-V compound material on a top surface of said solar cell structure;
forming a periodic array of holes of said window layer by using lithography and etching process to form a patterned window layer; and
depositing an anti-reflection coating film to cover said patterned window layer.

2. The method for fabricating a III-V compound semiconductor solar cell according to claim 1, wherein said lithography process comprises a photolithography process.

3. The method for fabricating a III-V compound semiconductor solar cell according to claim 1, wherein said step of depositing the anti-reflection coating film to cover said window layer includes sputtering or evaporation process.

4. The method for fabricating a III-V compound semiconductor solar cell according to claim 1, wherein said window layer comprises InAlP.

5. The method for fabricating a III-V compound semiconductor solar cell according to claim 1, wherein a size of each hole of said array of holes is between 5 μm and 20 μm.

6. A III-V compound semiconductor solar cell, comprising:
a solar cell structure comprising a patterned window layer comprised of III-V compound material including a periodic array of hole textures; and
an anti-reflection coating film covering said patterned window layer.

7. The III-V compound semiconductor solar cell according to claim 6, wherein said solar cell structure comprises:
a substrate;
an absorption layer formed over said substrate and said patterned window layer covering said absorption layer;
an front contact formed over portion of said patterned window layer; and
a rear contact formed below said substrate.

8. The III-V compound semiconductor solar cell according to claim 6, wherein a thickness of said patterned window layer is between 200 nm and 300 nm.

9. The III-V compound semiconductor solar cell according to claim 6, wherein said patterned window layer comprises InAlP.

10. The III-V compound semiconductor solar cell according to claim 6, wherein a size of each hole of said periodic array of holes is between 5 μm and 20 μm.
